(19) United States
(12) Patent Application Publication
(10) Pub. No.: US 2012/0041706 A1
(43) Pub. Date: Feb. 16, 2012

(54) TESTING SYSTEM FOR PORTABLE ELECTRONIC DEVICE

(75) Inventor: GUANG-CHEN LI, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/030,151

(22) Filed: Feb. 18, 2011

(30) Foreign Application Priority Data
Aug. 16, 2010 (CN) 201010254347.0

(51) Int. Cl. G06F 19/00; G01R 31/02

(52) U.S. Cl. 702/118

(57) ABSTRACT

A testing system for a portable electronic device includes a sequential control card, a plurality of test devices, and a plurality of switches. The sequential control card provides and outputs command signals according to a predetermined test sequence. The test devices test the portable electronic devices according to the test sequence. The switches are connected between the sequential control card and the corresponding test devices, and are switched on, in order, under the control of the command signal from the sequential control card according to the test sequence to activate the corresponding test devices. The test devices test the portable electronic device according to the predetermined test sequence.

### BACKGROUND

1. Technical field

The disclosure generally relates to testing systems, and more particularly to a testing system for portable electronic devices according to test sequence.

2. Description of the Related Art

In manufacturing, notebooks, mobile phones and other electronic devices require different tests, such as surface pressure tests, communication performance tests, video performance tests, and user interface (UI) performance tests, to obtain various performance indicators.

In such tests, computers are typically used to control test equipment to automatically test devices under test (DUT) of the electronic device and obtain different test parameters. However, in practice, test sequences of the DUT are difficult to control and manage, which may cause disordering of transmitting test commands and receiving test results. Thus, it is difficult to confirm the test result corresponding to each test command, which may reduce test efficiency and accuracy.

Therefore, there is room for improvement within the art.

### BRIEF DESCRIPTION OF THE DRAWINGS

Many aspects of an exemplary portable electronic device testing system can be better understood with reference to the following drawings. The components in the drawings are not necessarily drawn to scale, the emphasis instead being placed upon clearly illustrating the principles of the exemplary portable electronic device testing system. Moreover, in the drawings, like reference numerals designate corresponding parts throughout the several views. Wherever possible, the same reference numbers are used throughout the drawings to refer to the same or like elements of an embodiment.

FIG. 1 is a block diagram of a testing system for a portable electronic device including a sequential control card, a group of switches, a group of test devices, and a main controller, according to an exemplary embodiment.

FIG. 2 is a circuit view of the sequential control card, the group of switches and the main controller of the testing system of one embodiment of FIG. 1.

### DETAILED DESCRIPTION

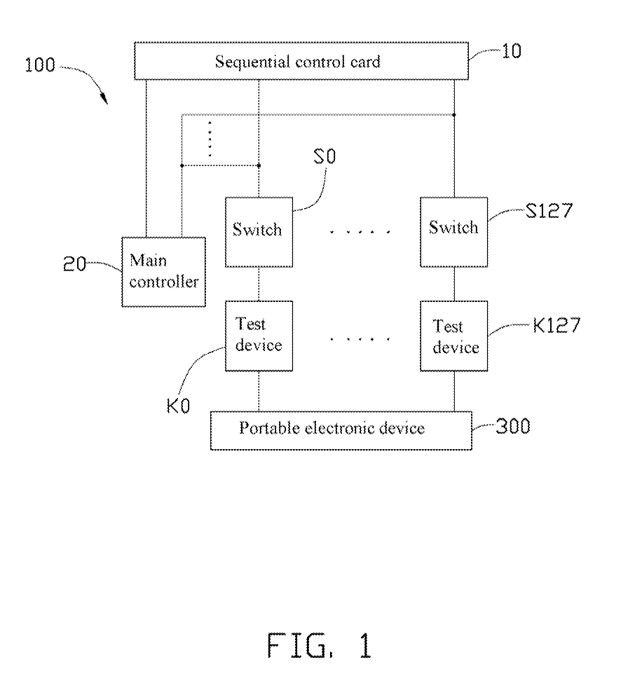

FIG. 1 is a block diagram of a testing system 100 for a portable electronic device 300 including a sequential control card 10, a group of switches S0-S127, and a group of test devices K0-K127, and a main controller 20, according to an exemplary embodiment. The testing system 100 can be used to test and manage the portable electronic device 300, such as a mobile phone, or a notebook, according to a predetermined test sequence.

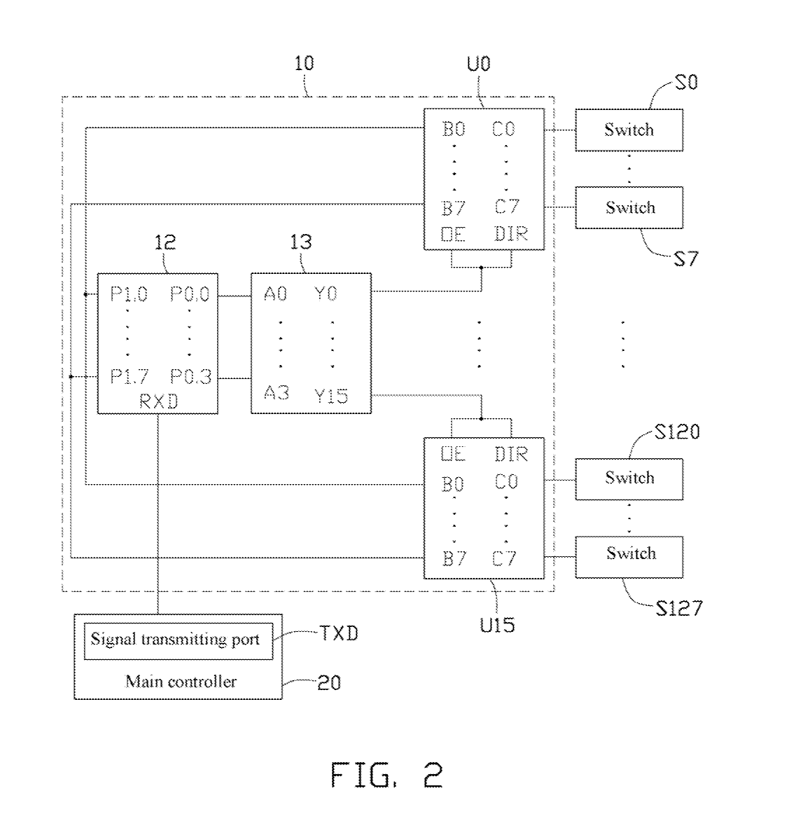

Also referring to FIG. 2, the sequential control card 10 includes a main control module 12, a timing selection module 13, and a group of data transmission modules U0-U15. The main control module 12 can be an AT89S52 microcontroller and includes a power port (not shown), a group of timing selection ports P0.0-P0.3, a group of signal control ports P1.0-P1.7, and a signal receiving port RXD. In this exemplary embodiment, the power port of the main control module 12 may be electrically connected to a battery (not shown).

The timing selection module 13 can be a DM74LS154N 4-line to 16-line decoder and includes a group of timing signal input ports A0-A3 and a group of timing signal output ports Y0-Y15. The timing signal input ports A0-A3 are electrically connected to the timing selection ports P0.0-P0.3, respectively. In detail, the timing signal input port A0 is electrically connected to the timing selection port P0.0, the timing signal input port A1 is electrically connected to the timing selection port P1, and the timing signal input port A3 is electrically connected to the timing selection port P0.3. The timing signal input ports A0-A3 receive high voltage signal (e.g., logic 1) or low voltage signal (e.g., logic 0) from the timing selection ports P0.0-P0.3 to logically and selectably control the level of the output voltage of the timing signal output ports Y0-Y15.

The timing selection ports P0.0-P0.3 are four logic ports and have sixteen different logic combinations, such as 0000, 0001, 0010 . . . 1110, 1111, corresponding to the timing signal output ports Y0-Y15. The timing signal input ports A0-A3 receive the logic combinations from the timing selection ports P0.0-P0.3, and one corresponding of the timing signal output ports Y0-Y15 outputs a high or a low voltage signal. In detail, for example, when the timing selection ports P0.0-P0.3 output the logic combination of 0000, the timing signal output port Y0 then outputs a low voltage signal, the timing signal output ports Y1-Y15 then output high voltage signals. Similarly, when the timing selection ports P0.0-P0.3 output the logic combination of 0001, the timing signal output port Y1 outputs a low voltage signal, the timing signal output ports Y0 and Y2-Y15 output high voltage signals. When the timing selection ports P0.0-P0.3 output the logic combination of 0011, the timing signal output port Y3 outputs a low voltage signal, the timing signal output ports Y0-Y2 and Y4-Y15 output high voltage signals. When the timing selection ports P0.0-P0.3 output the logic combination of 1111, the timing signal output port Y15 outputs a low voltage signal, the timing signal output ports Y0-Y14 output high voltage signals.

Each of the data transmission modules U0-U15 can be a SN74LS245N integrated circuit (IC) and includes a group of data input ports B0-B7, a group of data output ports C0-C7, and two enable signal ports OE and DIR. The enable signal ports OE and DIR are low enabled ports. The data input ports B0-B7 of each data transmission module are electrically connected to the signal control ports P1.0-P1.7, respectively. The enable signal ports OE and DIR of the data transmission modules U0-U15 are electrically connected to the timing signal output port Y0-Y15, respectively. In detail, the data input ports B1 of the data transmission modules U0-U15 are electrically connected to the signal control ports P1.1 of the signal control module 12, and the enable signal ports OE and DIR of the data transmission module U1 are electrically connected to the timing signal output port Y1. Similarly, the data input ports B2 of the data transmission modules U0-U15 are electrically connected to the signal control ports P1.2 of the signal control module 12, and the enable signal ports OE and DIR of the data transmission module U2 are electrically connected to the timing signal output port Y2.

In this exemplary embodiment, the data transmission module U0 is used as an example to illustrate the circuit connections of the data transmission module U0, the signal control module 12 and the timing selection module 13. The data input ports B0-B7 of the data transmission module U0 are electrically connected to the signal control ports P1.0-P1.7 of the signal control module 12 respectively, and the enable signal ports OE and DIR are electrically connected to the timing signal output port Y0 of the timing selection module 13. In detail, the timing selection ports P0.0-P0.3 output the logic combination of 0000, the timing signal output port Y0 then outputs a low voltage signal, the enable signal ports OE and DIR receive the low voltage signal and are enabled, and the data transmission module U0 is activated. Accordingly, the signal control ports P1.0-P1.7 provide and output corresponding command signals, such as logic 1, to the data transmission module U0 through the data input ports B0-B7 and the command signals are transmitted to the switches S0-S7 through the data output ports C0-C7 to activate one of the switches S0-S7. When the timing signal output port Y0 outputs a high voltage signal to the enable signal ports OE and DIR, the signal control ports P1.0-P1 stop the transmission of the command signals.

The switches S0-S127 can be relays. One end of each switch is electrically connected to the data output port of the data transmission modules U0-U15, and the other end of each switch is electrically connected to one corresponding of the test devices K0-K127. In detail, the switch S0 electrically connects the data output port C0 of the data transmission module U0 and the test device K0. The switch S9 electrically connects the data output port C1 of the data transmission module U1 and the test device K9. The switches S0-S127 are activated when receiving high voltage signals.

The main controller 20 can be a computer and is electrically connected to the switches S0-S127 through a printed circuit board (PCB), a flexible PCB (FPC), or a switch interface. The main controller 20 includes a signal transmitting port TXD, which is electrically connected to the signal receiving port RXD of the signal control module 12. The main controller 20 includes different control programs to provide different command signals for the signal control module 12.

Further referring to FIGS. 1 and 2, in testing, the test devices K0-K127 are electrically connected to devices under test (DUT) of the portable electronic device 300, respectively. For example, the test device K0 is used to test the camera performance and is electrically connected to the camera of the portable electronic device 300; the test device K1 is used to test communication performance and is electrically connected to the antenna of the portable electronic device 300; the test device K2 is used to test the user interface (UI) performance and is electrically connected to the touch panel and the liquid crystal display (LCD) of the portable electronic device 300. The test devices K0-K127 are then electrically connected to the switches S0-S127 and the switches S0-S127 are electrically connected to the main controller 20 through the FPC or the switch interface.

When testing the DUT of the portable electronic device 300 according to predetermined test sequence, the main controller 20 provides and outputs command signals to the signal control module 12 to activate the switches S0-S127 according to the predetermined test sequence. For example, the predetermined priority of K1 is higher than that of K0, and the predetermined priority of K0 is higher than that of the K2 according to the test sequence. Thus, the main controller 20 firstly sends a corresponding command signal to the signal control module 12 through the signal transmitting port TXD, the timing selection ports P0.0-P0.3 output the logic combination of 0001 to the timing signal input ports A0-A3, the timing signal output port Y1 outputs a low voltage signal, and the data transmission module U1 is activated and selected.

The main controller 20 then controls the signal control ports P1.0-P1.7 of the signal control module 12 to output a logic combination of 00000010 to the data input ports B0-B7 of the data transmission module U1, so the data output port C1 outputs a high voltage signal to the switch S1, and the switch S1 is selected and is switched on according to the high voltage signal. Thus, the test device K1 is activated and controlled to test the corresponding DUT of the portable electronic device 300. The main controller 20 receives the test result of the DUT of the portable electronic device 300 through the switch S0 and the sequential control card 10.

According, the main controller 20 sends another command signal to the signal control module 12 according test priority, the timing selection ports P0.0-P0.3 output the logic combination of 0000 to the timing signal input ports A0-A3, the timing signal output port Y0 outputs a low voltage signal, and the data transmission module U0 is activated and selected. The signal control ports P1.0-P1.7 of the signal control module 12 outputs a logic combination of 00000001 to the data input ports B0-B7 of the data transmission module U0, and the switch S1 is switched on. Thus, the test device K0 is activated to test the corresponding DUT of the portable electronic device 300.

Similarly, the timing selection ports P0.0-P0.3 output the logic combination of 0010 to the timing signal input ports A0-A3, and the data transmission module U2 is activated and selected. The signal control ports P1.0-P1.7 of the signal control module 12 output a logic combination of 00000100 to the data transmission module U3, and the switch S2 is selected and switched on. Thus, the test device K2 is then activated to test the corresponding DUT of the portable electronic device 300.

In summary, in the testing system for portable electronic device 100 of the exemplary embodiment, the switches S0-S127 are switched on or off under the control of the main controller 20 according to the predetermined test sequence, and the corresponding test devices K0-K127 are activated and controlled to test various performances of the portable electronic device 300 according to the test priority. In addition, the testing system 100 has a simple circuit connection, and can control and conduct a number of performance tests of one or more of the portable electronic device 300 according to the predetermined test sequence, which can improve test efficiency and accuracy.

It is to be understood, however, that even though numerous characteristics and advantages of the exemplary disclosure have been set forth in the foregoing description, together with details of the structure and function of the exemplary disclosure, the disclosure is illustrative only, and changes may be made in detail, especially in matters of shape, size, and arrangement of parts within the principles of exemplary disclosure to the full extent indicated by the broad general meaning of the terms in which the appended claims are expressed.

What is claimed is:

1. A testing system, comprising:
a sequential control card that provides and outputs command signals according to a predetermined test sequence;
a plurality of test devices electrically connected to portable electronic devices; and
a plurality of switches electrically connected between the sequential control card and the corresponding test devices, wherein the switches are switched on under the control of the command signal from the sequential control card according to the test sequence to activate the corresponding test devices, and the test devices test the portable electronic device according to the predetermined test sequence.

2. The testing system as claimed in claim 1, wherein the switches are relays.

3. The testing system as claimed in claim 1, wherein the sequential control cord comprises a main control module and a timing selection module, the main control module comprises a group of timing selection ports, the timing selection module comprises a group of timing signal input ports, the timing signal input ports are electrically connected to the timing selection ports respectively to receive the command signal from the timing selection ports to selectably control the level of the output voltage of the timing selection module.

4. The testing system as claimed in claim 3, wherein the sequential control cord further comprises a group of data transmission modules, each data transmission module comprises two enable signal ports, the timing selection module further comprises a group of timing signal output ports, the enable signal ports are low enabled ports, the enable signal ports of the data transmission modules are electrically connected to the timing signal output port respectively to receive the command signal to activate the data transmission modules.

5. The testing system as claimed in claim 4, wherein the timing selection ports of the signal control module output the command signal to the timing signal input ports, the corresponding timing signal output port outputs a low voltage signal (logic 0), the enable signal ports receive the low voltage signal and are enabled, and the corresponding data transmission module is activated.

6. The testing system as claimed in claim 5, wherein the main control module further comprises a group of signal control ports, each data transmission module further comprises a group of data input ports and a group of data output ports, the data input ports of each data transmission module are electrically connected to the signal control ports respectively, the data output ports of each data transmission module are electrically connected to the test devices, respectively.

7. The testing system as claimed in claim 6, wherein when the corresponding data transmission module is activated, the signal control ports output a corresponding command signal to the corresponding data transmission module through the data input ports and the command signals are transmitted to the switches through the data output ports to activate one of the switches.

8. The testing system as claimed in claim 3, wherein the timing selection module is a 4-line to 16-line decoder.

9. The testing system as claimed in claim 3, further comprising a main controller electrically connected to the switches, wherein the main controller comprises a signal transmitting port, the signal control module further comprises a signal receiving port, and the signal transmitting port is electrically connected to the signal receiving port to transmit different command signals.

10. The testing system as claimed in claim 9, wherein the main controller outputs the command signals to the signal control module through the signal transmitting port according the test sequence, the corresponding enable signal ports are enabled, the corresponding data transmission module is then activated and selected, the main controller then controls the signal control ports to output a command signal to the activated data transmission module, the corresponding data output port is selected, and the switch is selected and is switched on to drive the corresponding test device to test the portable electronic device.

11. A testing system, comprising:
a main controller that provides a command signal according to a predetermined test sequence;
a sequential control card electrically connected to the main controller, the sequential control card receiving the command signal to generate a corresponding logic combination signal;
a plurality of test devices electrically connected to portable electronic devices, the test devices testing the portable electronic devices under the control of the logic combination signal; and
a plurality of switches electrically connected between the sequential control card and the corresponding test devices, wherein the main controller provides a command signal to the sequential control card to generate a corresponding logic combination signal, one of the switches is selected and is switched on under the control of the logic combination from the sequential control card according to the test sequence, and the test device electrically connected to the selected switch is activated and controlled to test the portable electronic device according to the test sequence.

12. The testing system as claimed in claim 11, wherein the main controller is electrically connected to the switches, the main controller comprises a signal transmitting port, the sequential control card comprises a signal control module, and the signal control module comprises a signal receiving port, and the signal transmitting port is electrically connected to the signal receiving port to transmit command signal.

13. The testing system as claimed in claim 11, wherein the sequential control cord comprises a main control module and a timing selection module, the main control module comprises a group of timing selection ports, the timing selection module comprises a group of timing signal input ports, the timing signal input ports are electrically connected to the timing selection ports, respectively, to receive the logic combination signal from the timing selection ports to logically and selectably control the level of the output voltage of the timing selection module.

14. The testing system as claimed in claim 13, wherein the sequential control cord further comprises a group of data transmission modules, each data transmission module comprises two enable signal ports, the timing selection module further comprises a group of timing signal output ports, the enable signal ports are low enabled ports, the enable signal ports of the data transmission modules are electrically connected to the timing signal output port, respectively, to receive the logic combination signal to activate the data transmission modules.

15. The testing system as claimed in claim 14, wherein the timing selection ports of the signal control module output the logic combination signal to the timing signal input ports, the corresponding timing signal output port outputs a low voltage (logic 0) signal, the enable signal ports OE and DIR receive the low voltage signal and are enabled, and the corresponding data transmission module is activated.

16. The testing system as claimed in claim 15, wherein the main control module further comprises a group of signal control ports, each data transmission module further comprises a group of data input ports and a group of data output ports, the data input ports of each data transmission module are electrically connected to the signal control ports respectively, the data output ports of each data transmission module are electrically connected to the test devices, respectively.

17. The testing system as claimed in claim 16, wherein when the corresponding data transmission module is activated, the signal control ports output a corresponding logic combination signal to the corresponding data transmission module through the data input ports and the logic combination signal is transmitted to the switches through the data output ports to activate one of the switches.

18. The testing system as claimed in claim 16, wherein the main controller outputs the command signals to the signal control module through the signal transmitting port according the test sequence, the corresponding enable signal ports are enabled, the corresponding data transmission module is then activated and selected, the main controller then controls the signal control ports to output a logic combination signal to the activated data transmission module, the corresponding data output port is selected, and the switch is selected and is switched on to drive the corresponding test device to test the portable electronic device.

19. The testing system as claimed in claim 11, wherein the switches are logically switched controlled by the main controller to test different performances of the portable electronic device according to the test sequence, and the main controller orderly receives the test results of the portable electronic device through the switch and the sequential control card.

20. The testing system as claimed in claim 13, wherein the switches are relays, and the timing selection module is a 4-line to 16-line decoder.
